(19) United States
(12) Patent Application Publication
(10) Pub. No.: US 2025/0317137 A1
(43) Pub. Date: Oct. 9, 2025

(54) CONTROL CIRCUIT AND POWER SUPPLY CIRCUIT

(71) Applicant: FUJI ELECTRIC CO., LTD., Kanagawa (JP)

(72) Inventor: Yuki KUMAZAWA, Matsumoto-city (JP)

(21) Appl. No.: 19/061,949

(22) Filed: Feb. 24, 2025

(30) Foreign Application Priority Data
Apr. 3, 2024 (JP) 2024-060408

(51) Int. Cl. H03K 17/082; H02M 1/00; H02M 1/32; H02M 7/5387

(52) U.S. Cl. CPC H03K 17/0822; H02M 1/0009; H02M 1/32; H02M 7/53871

(57) ABSTRACT

There is provided a control circuit which includes a detection value comparison unit which compares a current detection value depending on a main current flowing through a power semiconductor and a set current threshold, a protection unit which, when a state in which the current detection value exceeds the current threshold has lasted longer than a set duration, suppresses the main current flowing through the power semiconductor, and a protection control unit which controls at least any one of the current threshold, the duration, or an extraction rate of electric charges from the control terminal, based on a control power supply voltage which determines an amplitude of a control signal.

The contents of the following patent application(s) are incorporated herein by reference: NO. 2024-060408 filed in JP on Apr. 3, 2024.

### BACKGROUND

### 1. Technical Field

The present invention relates to a control circuit and a power supply circuit.

### 2. Related Art

Patent Document 1 discloses, in claim 1, a semiconductor apparatus “which performs a protective operation for a switching device when a sense voltage, which is obtained by converting a sense current shunted from a main current flowing through the switching device into a voltage, exceeds a threshold.”

Patent Document 2 discloses, in claim 1, a semiconductor apparatus “which detects a main current flowing between main electrodes of a semiconductor device and performs a protective operation for the semiconductor device when the main current reaches a trip level.”

### PRIOR ART DOCUMENTS

### Patent Documents

Patent Document 1: Japanese Patent Application Publication No. 2013-77976

Patent Document 2: Japanese Patent Application Publication No. 2013-62730

### BRIEF DESCRIPTION OF THE DRAWINGS

FIG. 1 illustrates an example of a control circuit 100 according to one embodiment of the present invention.

FIG. 2 illustrates an example of a V_{CC} detection circuit 132.

FIG. 3 illustrates an example of a filter 110.

FIG. 4 illustrates a configuration example of a selection unit 103.

FIG. 5 illustrates another configuration example of the control circuit 100.

FIG. 6 illustrates another exemplary operation of a protection control unit 130.

FIG. 7 illustrates another exemplary operation of the protection control unit 130.

FIG. 8 is a graph for describing a short-circuit current I_{SC} and a short-circuit energy E_{SC} applied to a power semiconductor 200.

FIG. 9 illustrates an example of a power supply circuit 300 according to one embodiment of the present invention.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention. Note that in the present specification and the drawings, elements having substantially the same functions and configurations are denoted by the same reference numerals, and redundant descriptions for them are omitted. Elements not directly related to the present invention are also omitted from the drawings. Also, when elements having a same function and configuration are illustrated in one figure, one representative element may be denoted by a reference numeral and reference numerals for remaining elements may be omitted.

In the present specification, when a term such as “same” or “equal” is used, it may encompass an error due to a manufacturing variation or the like. The error is, for example, within 10%.

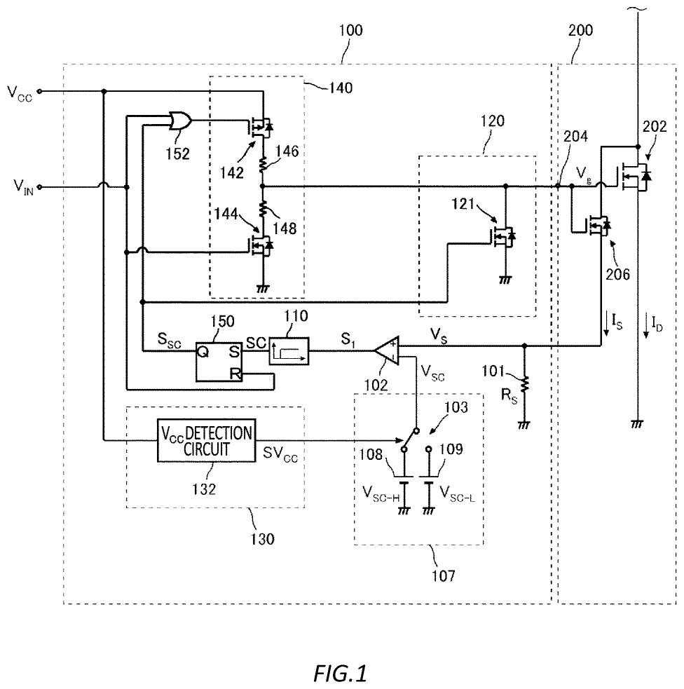

FIG. 1 illustrates an example of a control circuit 100 according to one embodiment of the present invention. The control circuit 100 controls a power semiconductor 200. The power semiconductor 200 operates depending on a control signal V_{g} applied to a control terminal 204. The power semiconductor 200 of the present example includes a main device 202 and a sense device 206. The power semiconductor 200 may be formed on a silicon substrate or a compound semiconductor substrate such as SiC.

The main device 202 of the present example is a transistor such as an IGBT or a MOSFET. The main device 202 passes a main current I_{D} which depends on the control signal V_{g} applied to the control terminal 204. The main current I_{D} is, for example, a drain current in the MOSFET or a collector current in the IGBT. The sense device 206 passes a sense current I_{S} which depends on the main current I_{D} through the main device 202. The sense device 206 may be formed on a same chip as the main device 202 or may be formed on a different chip.

The sense device 206 of the present example is an IGBT or a MOSFET provided in parallel with the main device 202. A gate terminal of the sense device 206 is applied with the control signal V_{g}, which is the same as that applied to a gate terminal of the main device 202. In the present example, a ratio between the main current I_{D} and the sense current I_{S} is determined depending on a ratio between channel areas of the main device 202 and the sense device 206. That is, the sense current I_{S} flowing through the sense device 206 of the present example is proportional to the main current I_{D}. As an example, the sense current I_{S} is 1/1000 or less and 1/100000 or more of the main current I_{D}. A channel area is an area of a region where a channel is formed, in a cross section perpendicular to a direction of a current flow. A so-called channel width may be used as the channel area.

The control circuit 100 detects whether an overcurrent is flowing through the main device 202 by sensing the sense current I_{S}. For example, when the main device 202 is a device for an upper arm or a lower arm in an inverter circuit, if devices for the upper arm and the lower arm turn into an ON state simultaneously, then a large short-circuit current will flow through the main device 202. The short-circuit current is an example of the overcurrent. Though the present specification describes an operation of the control circuit 100 when the short-circuit current flows through the main device 202, the control circuit 100 may operate similarly when another kind of overcurrent flows through the main device 202.

When the control circuit 100 determines that the short-circuit current is flowing through the main device 202, it suppresses the main current ID flowing through the main device 202. For example, when the control circuit 100 detects the short-circuit current, it forces the main device 202 to turn into an OFF state. Such control enables protection of the main device 202 from the short-circuit current.

A magnitude of the short-circuit current flowing through the main device 202 or a short-circuit energy applied to the main device 202 varies depending on the control signal V_{g} applied to the main device 202. As an example, the larger a voltage value of the control signal V_{g}, the larger the short-circuit current or the short-circuit energy applied to the main device 202. When the short-circuit current or the short-circuit energy applied to the main device 202 is larger, it is more likely to exceed a short-circuit withstand capability of the main device 202, causing the main device 202 to become more prone to destruction. In particular, when the main device 202 is made of SiC, the short-circuit withstand capability is likely to be smaller and the short-circuit energy applied to the main device 202 becomes more prone to exceed the short-circuit withstand capability.

The control circuit 100 of the present example suppresses the main current I_{D} flowing through the main device 202 depending on a control power supply voltage V_{CC} which determines an amplitude of the control signal V_{g}. This enables more appropriate protection of the main device 202. For example, when the control power supply voltage V_{CC} is higher, the control circuit 100 cuts off the main current I_{D} of the main device 202 at an earlier timing. This suppresses the destruction of the main device 202. The control power supply voltage V_{CC} may be a voltage which determines a maximum value of the control signal V_{g}. A minimum value of the control signal V_{g} may be determined by a reference potential such as 0 V. Controlling the main current I_{D} depending on the control power supply voltage V_{CC} will be described later.

The control power supply voltage V_{CC} and the input signal V_{IN} are input to the control circuit 100 of the present example. The input signal V_{IN} is a signal input externally to control an operation of the power semiconductor 200. The input signal V_{IN} of the present example is a signal which indicates a first logical value such as L logic within a period where the power semiconductor 200 should assume an ON state and indicates a second logical value such as H logic within a period where the power semiconductor 200 should assume an OFF state. The control circuit 100 generates the control signal V_{g} which has a waveform pattern corresponding to the logical value of the input signal V_{IN} and has the amplitude depending on the control power supply voltage V_{CC}.

The control circuit 100 includes a detection value comparison unit 102, a protection unit 120, and a protection control unit 130. The control circuit 100 of the present example further includes a detection resistor 101, a current threshold generation unit 107, a filter 110, a set/reset latch 150, an OR circuit 152, and a charge and discharge control unit 140.

The charge and discharge control unit 140 generates the control signal V_{g} based on the control power supply voltage V_{CC}, the reference potential, and the input signal V_{IN}. The charge and discharge control unit 140 of the present example includes a charge device 142, a discharge device 144, a charge resistor 146, and a discharge resistor 148. Each of the charge device 142 and the discharge device 144 is a transistor which switches depending on the input signal V_{IN}. The charge device 142 of the present example is a P-channel MOSFET, and the discharge device 144 is an N-channel MOSFET. The charge device 142 is provided between a terminal to which the control power supply voltage V_{CC} is applied and the control terminal 204 or the discharge device 144. The discharge device 144 is provided between the charge device 142 and the reference potential. The discharge device 144 of the present example is provided between the discharge resistor 148 and the reference potential. The charge resistor 146 is provided between the charge device 142 and the discharge device 144. The discharge resistor 148 is provided between the charge resistor 146 and the discharge device 144. A connection point between the charge resistor 146 and the discharge resistor 148 is connected to the control terminal 204 of the power semiconductor 200.

In the present example, when the input signal V_{IN} becomes the L logic, the charge device 142 turns into an ON state and the discharge device 144 turns into an OFF state. In this way, the control terminal 204 is applied with the control power supply voltage V_{CC} via the charge resistor 146, and a gate capacitance of the control terminal 204 will be charged. Accordingly, the voltage value of the control signal V_{g} increases. When the control signal V_{g} becomes higher than a threshold voltage of the main device 202, the main device 202 transitions to an ON state. A threshold voltage of the sense device 206 is similar to the threshold voltage of the main device 202. Thus, the sense device 206 switches in synchronism with the main device 202.

When the input signal V_{IN} becomes the H logic, the charge device 142 turns into an OFF state and the discharge device 144 turns into an ON state. In this way, the control terminal 204 is connected to the reference potential via the discharge resistor 148, and the gate capacitance of the control terminal 204 will be discharged. Accordingly, the voltage value of the control signal V_{g} decreases. When the control signal V_{g} becomes lower than the threshold voltage of the main device 202, the main device 202 transitions to an OFF state. The control circuit 100 operates in such a manner to control switching of the power semiconductor 200 depending on the input signal V_{IN}.

The detection resistor 101 is provided between the sense device 206 and the reference potential. The sense current I_{S} output by the sense device 206 flows through the detection resistor 101. In this way, the detection resistor 101 generates a sense voltage V_{S} which depends on a product of the sense current I_{S} and a resistance value R_{S}.

The detection value comparison unit 102 compares a current detection value depending on the main current I_{D} flowing through the main device 202 (a voltage value of the sense voltage V_{S} in the present example) with a voltage value of a set current threshold V_{SC}. The detection value comparison unit 102 is an operational amplifier in which the sense voltage V_{S} is input to its positive input terminal and the current threshold V_{SC} is input to its negative input terminal. The detection value comparison unit 102 outputs a current comparison result S₁ which indicates whether the sense voltage V_{S} exceeds the current threshold V_{SC}. The current comparison result S₁ of the present example is a signal which indicates H logic when the current detection value exceeds the current threshold and indicates L logic when the current detection value is less than or equal to the current threshold.

The filter 110 outputs a period determination signal SC which indicates whether a state in which the sense voltage V_{S} exceeds the current threshold V_{SC}, namely a state in which the current comparison result S₁ indicates the H logic, has lasted longer than a set duration. The period determination signal SC of the present example indicates H logic when a state in which the current comparison result S₁ indicates the H logic has lasted longer than a predetermined duration, or else it indicates L logic. The filter 110 is, for example, a low-pass filter which removes a predetermined high-frequency component. The duration can be adjusted by controlling a cut-off frequency in the filter 110. The control circuit 100 in another example may not have the filter 110 or a duration setting. That is, the duration may be zero. In this case, the current comparison result S₁ is input to a set terminal S of the set/reset latch 150, and current suppression for the main current I_{D} starts when the current detection value exceeds the current threshold.

When the period determination signal SC indicates the H logic, the protection unit 120 suppresses the main current I_{D} flowing through the main device 202. The protection unit 120 of the present example connects, regardless of the logical value of the input signal V_{IN}, the control terminal 204 of the power semiconductor 200 to the reference potential while the period determination signal SC indicates the H logic. This decreases the voltage value of the control signal V_{g} and suppresses the main current I_{D}.

The protection unit 120 of the present example includes a first protection device 121. When the state in which the sense voltage V_{S} exceeds the current threshold V_{SC} has lasted longer than the set duration, the first protection device 121 suppresses the main current ID flowing through the power semiconductor. The first protection device 121 of the present example is a MOSFET where a signal which depends on the period determination signal SC is input to its gate terminal. The first protection device 121 switches whether the control terminal 204 of the power semiconductor 200 is connected to the reference potential, depending on the signal input to the gate terminal. Turning the first protection device 121 into an ON state causes electric charges of the gate capacitance of the control terminal 204 to be extracted, thereby turning the power semiconductor 200 into the OFF state. In this way, the main current I_{D} is suppressed.

A protection signal S_{SC} output by the set/reset latch 150 is input to the gate terminal of the first protection device 121 of the present example. The first protection device 121 of the present example turns into the ON state when the protection signal S_{SC} indicates H logic and it turns into an OFF state when the protection signal S_{SC} indicates L logic.

The set/reset latch 150 retains and outputs a logical value of the current comparison result S₁ in the detection value comparison unit 102 (a logical value of the period determination signal SC in the present example), and sets its output as an initial value when the input signal V_{IN} indicates a logical value which represents that the power semiconductor 200 should be turned off. In the set/reset latch 150 of the present example, the period determination signal SC is input to its set terminal S, the input signal V_{IN} is input to its reset terminal R, and the protection signal S_{SC} is output from its output terminal Q. The set/reset latch 150 of the present example continues to output the protection signal S_{SC} of the H logic from a timing when the period determination signal SC transitions from the L logic to the H logic to a timing when the input signal V_{IN} transitions from the L logic to the H logic. When the period determination signal SC has remained in the H logic after the input signal V_{IN} has transitioned from the L logic to the H logic, the set/reset latch 150 may output the protection signal S_{SC} of the H logic. When the period determination signal SC indicates the L logic at a timing when the input signal V_{IN} transitions from the L logic to the H logic, the set/reset latch 150 may output the protection signal S_{SC} of the L logic.

The OR circuit 152 outputs a logical OR of the protection signal S_{SC} output by the set/reset latch 150 and the input signal V_{IN}. The charge and discharge control unit 140 controls whether the gate capacitance of the control terminal 204 of the power semiconductor 200 is charged, depending on an output of the OR circuit 152. When both the input signal V_{IN} and the protection signal S_{SC} indicate the L logic, the OR circuit 152 of the present example controls the charge device 142 to assume the ON state. When at least one of the input signal V_{IN} or the protection signal S_{SC} indicates the H logic, the OR circuit 152 may control the charge device 142 to assume the OFF state.

The control circuit 100 uses such configuration to protect the power semiconductor 200 when the overcurrent occurs while switching the power semiconductor 200 depending on the input signal V_{IN}. Note that, as described above, the control circuit 100 suppresses the main current I_{D} flowing through the main device 202 depending on the control power supply voltage V_{CC} which determines the amplitude of the control signal V_{g}.

The protection control unit 130 controls at least any one of the current threshold V_{SC}, the predetermined duration determined by the filter 110, or an extraction rate of the electric charges from the control terminal 204 based on the control power supply voltage V_{CC}. The protection control unit 130 in the example of FIG. 1 controls the current threshold V_{SC} based on the control power supply voltage V_{CC}.

The protection control unit 130 includes a V_{CC} detection circuit 132. The V_{CC} detection circuit 132 outputs a voltage comparison result SV_{CC} depending on a level of the control power supply voltage V_{CC}. The voltage comparison result SV_{CC} may be a binary signal which indicates whether the control power supply voltage V_{CC} exceeds a predetermined voltage threshold, or may be a signal which indicates the level of the control power supply voltage V_{CC} in three or more values. The protection control unit 130 controls the current threshold V_{SC} generated by the current threshold generation unit 107 based on the voltage comparison result SV_{CC}.

The current threshold generation unit 107 selects and outputs a current threshold among a plurality of preset current thresholds, depending on the voltage comparison result SV_{CC}. The current threshold generation unit 107 of the present example includes a selection unit 103, a threshold power supply 108, and a threshold power supply 109. The threshold power supply 108 generates a current threshold V_{SC-H}. The threshold power supply 109 generates a current threshold V_{SC-L} which is lower than the current threshold V_{SC-H}. The current threshold V_{SC-L} may be 75% or less, 50% or less, or 25% or less of the current threshold V_{SC-H}.

The selection unit 103 selects and outputs a current threshold depending on the voltage comparison result SV_{CC}. The selection unit 103 of the present example selects the current threshold V_{SC-L} when the control power supply voltage V_{CC} exceeds the voltage threshold, or selects the current threshold V_{SC-H} when the control power supply voltage V_{CC} is less than or equal to the voltage threshold. That is, the current threshold generation unit 107 may make the current threshold V_{SC} lower when the control power supply voltage V_{CC} is higher.

When the current threshold V_{SC} is lowered, the current comparison result S₁ indicates the H logic to start the current suppression at a lower sense voltage V_{S}. When a temporal waveform of the sense voltage V_{S} fluctuates with a predetermined gradient, lowering the current threshold V_{SC} enables earlier detection of an increase in the sense voltage V_{S} and an earlier start of suppressing the main current I_{D}. In this way, a timing for starting the current suppression can be adjusted depending on the control power supply voltage V_{CC}, and the power semiconductor 200 can be protected more appropriately.

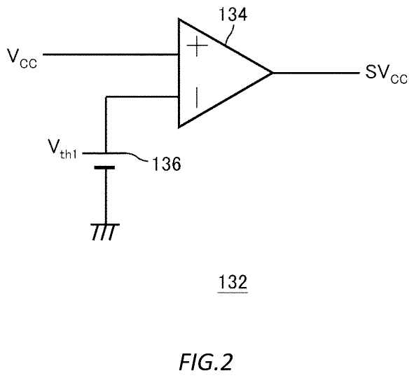

FIG. 2 illustrates an example of the V_{CC} detection circuit 132. The V_{CC} detection circuit 132 of the present example determines whether the control power supply voltage V_{CC} exceeds a predetermined voltage threshold Vₜₕ₁. The V_{CC} detection circuit 132 of the present example includes an operational amplifier 134 and a threshold power supply 136.

The threshold power supply 136 generates a voltage depending on the voltage threshold Vₜₕ₁. In the operational amplifier 134, a control power supply voltage V_{CC} is input to its positive input terminal and a voltage threshold Vₜₕ₁ is input to its negative input terminal. The operational amplifier 134 outputs the current comparison result S₁ which indicates the H logic when the control power supply voltage V_{CC} exceeds the voltage threshold Vₜₕ₁ and indicates the L logic when the control power supply voltage V_{CC} is less than or equal to the voltage threshold Vₜₕ₁.

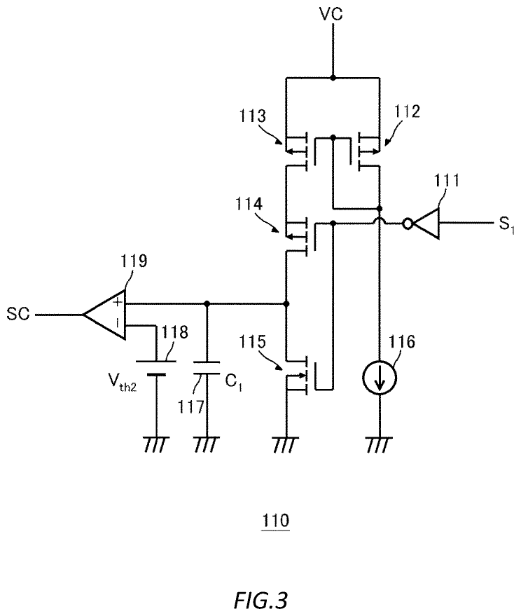

FIG. 3 illustrates an example of the filter 110. The filter 110 of the present example includes an inverter 111, transistors 112 to 115, a current source 116, a capacitor 117, an operational amplifier 119, and a threshold power supply 118.

The inverter 111 inverts and outputs the logical value of the current comparison result S₁. The transistor 112 is provided between a power supply voltage VC and a reference potential. The transistor 112 of the present example is a P-channel MOSFET in which its source terminal is applied with the power supply voltage VC and its drain terminal and gate terminal are connected. The current source 116 is provided between the drain terminal of the transistor 112 and the reference potential and determines a current flowing through the transistor 112.

The transistor 113 is a P-channel MOSFET provided in parallel with the transistor 112. A source terminal of the transistor 113 is applied with the power supply voltage VC, and its gate terminal is connected to the drain terminal of the transistor 112. A current equivalent to the transistor 112 flows through the transistor 113.

The transistor 114 is a P-channel MOSFET in which its source terminal is connected to the drain terminal of the transistor 113 and its gate terminal is connected to an output terminal of the inverter 111. When the current comparison result S₁ indicates the H logic, the transistor 114 is controlled to assume an ON state.

The transistor 115 is an N-channel MOSFET in which its drain terminal is connected to the drain terminal of the transistor 113, its source terminal is applied with the reference potential, and its gate terminal is connected to the output terminal of the inverter 111. When the current comparison result S₁ indicates the L logic, the transistor 114 is controlled to assume an ON state.

In the present example, the transistor 114 and the transistor 115 are controlled such that one assumes the ON state while another assumes the OFF state. The drain terminals of the transistor 114 and the transistor 115 are connected to the capacitor 117. When the transistor 114 becomes the ON state, the capacitor 117 is charged with a current of a magnitude determined by the current source 116 and a voltage across the capacitor gradually increases. Also, when the transistor 115 becomes the ON state, the capacitor 117 is discharged and the voltage across the capacitor gradually decreases.

For the operational amplifier 119, its positive input terminal is connected to the capacitor 117 and its negative input terminal is applied with a voltage threshold Vₜₕ₂. The operational amplifier 119 outputs the period determination signal SC which indicates the H logic when the voltage across the capacitor 117 exceeds the voltage threshold Vₜₕ₂ and indicates the L logic when the voltage across the capacitor 117 is less than or equal to the voltage threshold Vₜₕ₂. As described above, when the current comparison result S₁ indicates the H logic, that is, when the overcurrent is detected, the capacitor 117 is charged and the voltage across the capacitor 117 gradually increases. When the voltage across the capacitor 117 exceeds the voltage threshold Vₜₕ₂, the period determination signal SC becomes an H logic value. A gradient of the voltage waveform of the capacitor 117 is determined depending on a capacitance C₁ of the capacitor 117. Thus, a period from when the capacitor 117 starts charging to when the voltage across the capacitor 117 exceeds the voltage threshold Vₜₕ₂ is determined by the capacitance C₁. Thus, when the current comparison result S₁ has continued to indicate the H logic over a period depending on the capacitance C₁, the period determination signal SC indicates the H logic value. The period depending on the capacitance C₁ corresponds to the duration described above.

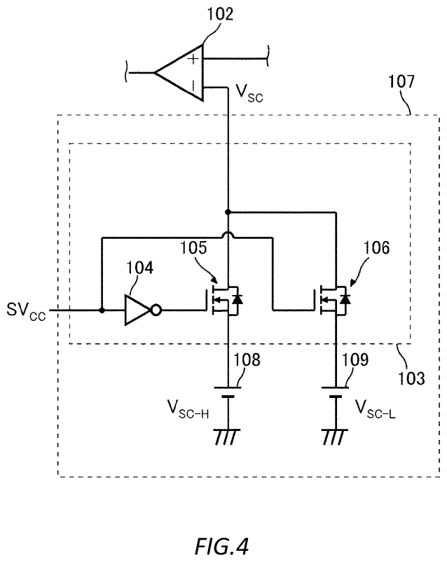

FIG. 4 illustrates a configuration example of the selection unit 103. The selection unit 103 of the present example includes an inverter 104, a transistor 105, and a transistor 106. The inverter 104 inverts and outputs the logical value of the voltage comparison result SV_{CC}.

The transistor 105 switches whether the threshold power supply 108 and the negative input terminal of the detection value comparison unit 102 are connected. The transistor 105 of the present example is an N-channel MOSFET in which its drain terminal is connected to the negative input terminal of the detection value comparison unit 102, its source terminal is connected to the threshold power supply 108, and its gate terminal is applied with an output from the inverter 104.

The transistor 106 switches whether the threshold power supply 109 and the negative input terminal of the detection value comparison unit 102 are connected. The transistor 106 of the present example is an N-channel MOSFET in which its drain terminal is connected to the negative input terminal of the detection value comparison unit 102, its source terminal is connected to the threshold power supply 109, and its gate terminal is applied with the voltage comparison result SV_{CC}. Such configuration enables the current threshold V_{SC-L} to be selected when the control power supply voltage V_{CC} exceeds the voltage threshold Vₜₕ₁ or the current threshold V_{SC-H} to be selected when the control power supply voltage V_{CC} is less than or equal to the voltage threshold Vₜₕ₁.

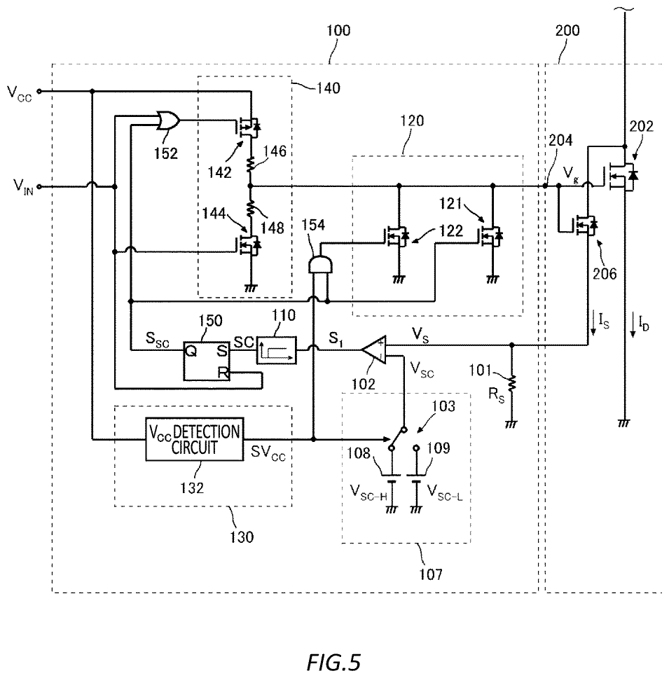

FIG. 5 illustrates another configuration example of the control circuit 100. The control circuit 100 of the present example further includes an AND circuit 154 and a second protection device 122 compared to the configuration of the control circuit 100 illustrated in FIGS. 1 to 4. Another configuration is similar to any one of aspects illustrated in FIGS. 1 to 4.

The second protection device 122 is provided in parallel with the first protection device 121 in the protection unit 120. The second protection device 122 of the present example is an N-channel MOSFET in which its drain terminal is connected to the control terminal 204 and its source terminal is connected to a reference potential. The AND circuit 154 inputs a logical AND of the protection signal S_{SC} and the voltage comparison result SV_{CC} to a gate terminal of the second protection device 122.

The protection unit 120 of the present example includes the first protection device 121 and the second protection device 122 provided in parallel. Each of the first protection device 121 and the second protection device 122 is an example of an extraction transistor which controls whether the control terminal 204 is connected to the reference potential. The first protection device 121 and the second protection device 122 may be collectively treated as one extraction transistor. When suppressing the main current I_{D}, states of the first protection device 121 and the second protection device 122 are controlled so as to control a channel area of each extraction transistor, thereby enabling an adjustment of the extraction rate of the electric charges from the gate capacitance of the control terminal 204.

The first protection device 121 of the present example operates depending on the protection signal S_{SC} output by the set/reset latch 150. While the protection signal S_{SC} indicates the H logic, the first protection device 121 always assumes the ON state and the main current I_{D} is suppressed.

The second protection device 122 of the present example operates based on the logical AND of the protection signal S_{SC} output by the set/reset latch 150 and the voltage comparison result SV_{CC}. When both the protection signal S_{SC} and the voltage comparison result SV_{CC} indicate the H logic, the second protection device 122 additionally assumes an ON state to accelerate an interruption of the power semiconductor 200, thereby enabling further suppression of the main current I_{D}. As described above, the H logic of the protection signal S_{SC} means that the state in which the sense voltage V_{S} exceeds the current threshold V_{SC} has lasted longer than the set duration. Also, the H logic of the voltage comparison result SV_{CC} means that the control power supply voltage V_{CC} exceeds the set voltage threshold Vₜₕ₁.

The protection control unit 130 of the present example inputs the voltage comparison result SV_{CC} to the AND circuit 154. In this way, the protection control unit 130 controls the extraction rate of the electric charges from the gate capacitance of the control terminal 204 based on the control power supply voltage V_{CC}. When the overcurrent is detected and the control power supply voltage V_{CC} exceeds the voltage threshold Vₜₕ₁, the protection control unit 130 of the present example causes the second protection device 122 to additionally become the ON state to increase the extraction rate of the electric charges. A magnitude of a current flowing through the second protection device 122 may be the same as or different from a magnitude of a current flowing through the first protection device 121. Also, when the voltage comparison result SV_{CC} has three or more values, the protection unit 120 may extract the electric charges from the control terminal 204 with a current amount depending on a value of the voltage comparison result SV_{CC}.

According to the present example, when the control power supply voltage V_{CC} is high, increasing the extraction rate of the electric charges from the control terminal 204 enables earlier suppression of the main current I_{D}. On the other hand, when the control power supply voltage V_{CC} is not high, decreasing the extraction rate of the electric charges from the control terminal 204 enables suppression of a surge.

In the example of FIG. 5, the protection control unit 130 controls both the extraction rate of the electric charges in the protection unit 120 and the current threshold V_{SC} generated by the current threshold generation unit 107. In another example, the protection control unit 130 may control the extraction rate of the electric charges in the protection unit 120 and may not control the current threshold V_{SC}.

In the example of FIG. 5, the protection control unit 130 controls the channel area of the extraction transistor in the protection unit 120. In another example, the protection control unit 130 may control a level of a gate voltage applied to the extraction transistor. The protection control unit 130 may control the gate voltage to become higher when the control power supply voltage V_{CC} is higher. In this way, the extraction rate of the electric charges can be increased when the control power supply voltage V_{CC} is higher.

The protection control unit 130 may control at least one of the channel area or the gate voltage. The protection control unit 130 may control an amplitude of the protection signal S_{SC} output by the set/reset latch 150 to control the gate voltage. The amplitude of the protection signal S_{SC} can be adjusted by adjusting a power supply voltage supplied to an output circuit of the set/reset latch 150.

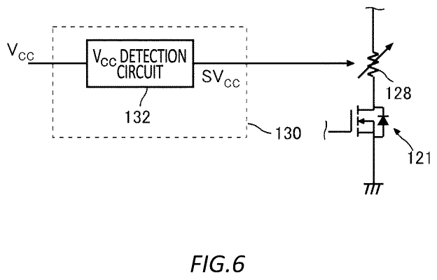

FIG. 6 illustrates another exemplary operation of the protection control unit 130. The protection unit 120 of the present example further includes a variable resistor 128. The variable resistor 128 is an example of a discharge resistor provided on a discharge path for discharging the control terminal 204. The variable resistor 128 is provided in series with the first protection device 121. The protection control unit 130 may control a resistance value of the variable resistor 128 to control the current flowing through the first protection device 121, thereby controlling the extraction rate of the electric charges from the gate capacitance of the control terminal 204. The protection control unit 130 may make the resistance value of the variable resistor 128 lower when the control power supply voltage V_{CC} is higher. In this way, the extraction rate of the electric charges can be increased when the control power supply voltage V_{CC} is higher.

The variable resistor 128 may also be provided for the second protection device 122. The protection control unit 130 may control the extraction rate of the electric charges by controlling at least any one of the resistance value of the variable resistor 128, the channel area of the extraction transistor, or the gate voltage of the extraction transistor.

The protection control unit 130 may control a resistance value of the discharge resistor 148 (see FIG. 1 or FIG. 5) based on the voltage comparison result SV_{CC}. The discharge resistor 148 is an example of a discharge resistor provided on the discharge path for discharging the control terminal 204. The protection control unit 130 may make the resistance value of the discharge resistor 148 lower when the control power supply voltage V_{CC} is higher. In this way, a discharge rate of the control terminal 204 by the discharge device 144 can be controlled.

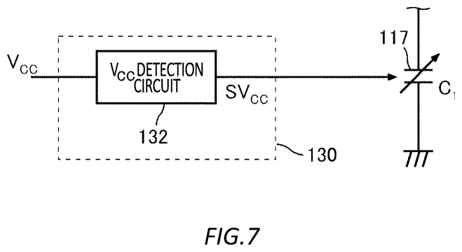

FIG. 7 illustrates another exemplary operation of the protection control unit 130. The protection control unit 130 of the present example controls the duration set in the filter 110 based on the voltage comparison result SV_{CC}. The protection control unit 130 may set the duration as shorter when the control power supply voltage V_{CC} is higher. In this way, the main current I_{D} can be suppressed earlier when the control power supply voltage V_{CC} is higher.

For example, when the capacitor 117 of the filter 110 has a variable capacitance, the protection control unit 130 may make a capacitance of the capacitor 117 smaller when the control power supply voltage V_{CC} is higher. In this way, a shorter duration can be set when the control power supply voltage V_{CC} is higher. Also, when the current source 116 illustrated in FIG. 3 is a variable current source, the protection control unit 130 may make a current delivered by the current source 116 larger when the control power supply voltage V_{CC} is higher. In this way, the shorter duration can be set when the control power supply voltage V_{CC} is higher. Also, when the threshold power supply 118 illustrated in FIG. 3 is a variable power supply, the protection control unit 130 may make the voltage threshold Vₜₕ₂ lower when the control power supply voltage V_{CC} is higher. In this way, the shorter duration can be set when the control power supply voltage V_{CC} is higher.

The protection control unit 130 may combine and perform two or more of controlling the duration set in the filter 110, controlling the current threshold V_{SC}, and controlling the extraction rate of the electric charges from the control terminal 204. When combining controlling the current threshold V_{SC} depending on the control power supply voltage V_{CC} and controlling the extraction rate of the electric charges depending on the control power supply voltage V_{CC}, the protection control unit 130 may change the current threshold V_{SC} and then control extraction transistors of which the extraction rate has changed, such as the first protection device 121 and the second protection device 122, to assume an ON state.

In this case, an extraction rate setting may be changed before the current threshold V_{SC} is changed. For example, the protection control unit 130 may change the extraction rate setting, change the current threshold V_{SC} to be input to the detection value comparison unit 102, and then control the extraction transistors to assume the ON state. The extraction rate setting may be changed simultaneously with or after the change in the current threshold V_{SC}. If the extraction transistors of which the extraction rate has changed are controlled to assume the ON state before the current threshold V_{SC} is changed, a voltage of the control signal V_{g} will decrease even under a normal condition without the overcurrent. The duration set in the filter 110 may be controlled before, simultaneously with, or after the current threshold V_{SC} is changed.

A timing of starting the suppression of the main current ID can be adjusted by adjusting the resistance value of the detection resistor 101 to adjust a gain of the sense voltage V_{S}. However, the sense voltage V_{S} may be used for applications other than detecting the overcurrent, such as calculating a current value of the main current I_{D}. Thus, changing the gain of the sense voltage V_{S} will affect these applications. According to the control circuit 100 of the present example, a timing for suppressing the main current I_{D} can be adjusted without adjusting the resistance value of the detection resistor 101.

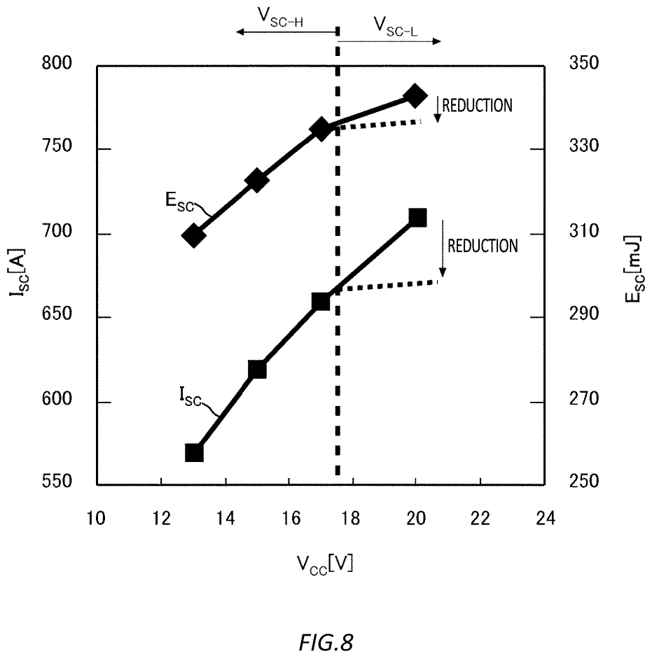

FIG. 8 is a graph for describing a short-circuit current I_{SC} and a short-circuit energy E_{SC} applied to the power semiconductor 200. In FIG. 8, a horizontal axis represents the control power supply voltage V_{CC} and a vertical axis represents the short-circuit current I_{SC} and the short-circuit energy E_{SC}.

Graphs with solid lines in FIG. 8 show a comparative example in which the current threshold V_{SC} is not changed. In this case, a constant current threshold V_{SC-H} is used. As the control power supply voltage V_{CC} increases, both the short-circuit current I_{SC} and the short-circuit energy E_{SC} increase.

Graphs with dotted lines in FIG. 8 show an example in which the current threshold V_{SC} is switched depending on the control power supply voltage V_{CC}. Specifically, the current threshold V_{SC-L} is selected when the control power supply voltage V_{CC} exceeds 17.5 V, or the current threshold V_{SC-H} is selected when the control power supply voltage V_{CC} is less than or equal to 17.5 V. As shown in FIG. 8, both the short-circuit current I_{SC} and the short-circuit energy E_{SC} are reduced by selecting the current threshold V_{SC-L}. This can suppress destruction of the power semiconductor 200. Though FIG. 8 shows an example in which the current threshold V_{SC} is controlled, both the short-circuit current I_{SC} and the short-circuit energy E_{SC} can be reduced similarly in examples in which the extraction rate of the electric charges or the duration is controlled.

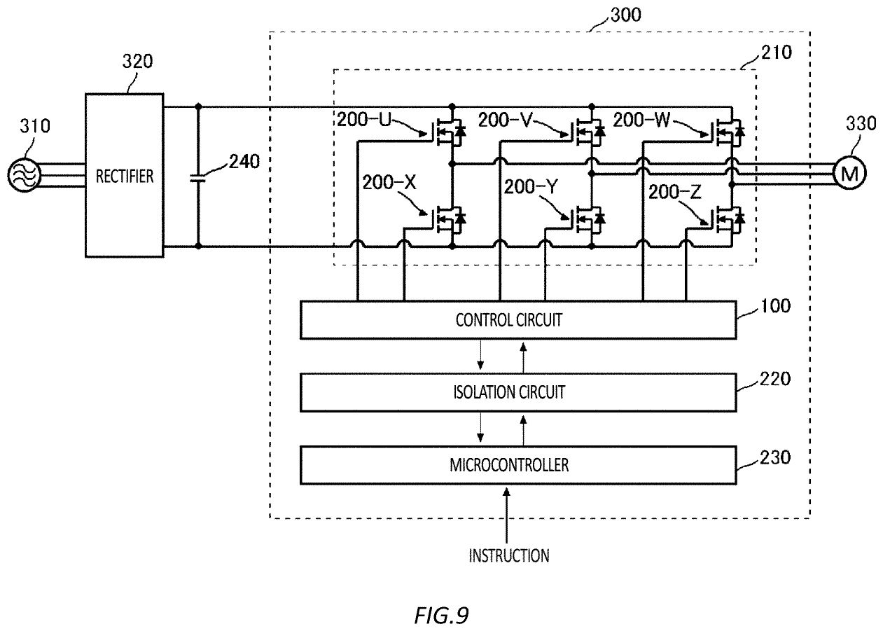

FIG. 9 illustrates an example of a power supply circuit 300 according to one embodiment of the present invention. The power supply circuit 300 supplies electrical power to a load 330 depending on electrical power supplied from an external power supply 310. AC electrical power output from the external power supply 310, which has been rectified by a rectifier 320 and a capacitor 240, is input to the power supply circuit 300 of the present example. The load 330 is a three-phase motor, for example, but is not limited thereto.

The power supply circuit 300 includes a semiconductor module 210, the control circuit 100, an isolation circuit 220, and a microcontroller 230. The semiconductor module 210 supplies the electrical power to the load 330 based on electrical power supplied by the rectifier 320. The semiconductor module 210 includes at least one power semiconductor 200 described in FIGS. 1 to 8. Power semiconductors 200 are operated to supply the electrical power to the load 330.

The semiconductor module 210 of the present example is a three-phase inverter. The semiconductor module 210 includes the power semiconductor 200 for an upper arm and the power semiconductor 200 for a lower arm in a respective inverter for each phase. In the example of FIG. 9, the power semiconductor 200-U and 200-X correspond to the upper arm and the lower arm for one phase. The same applies to the power semiconductor 200-V and 200-Y, and the power semiconductor 200-W and 200-Z.

In the example of FIG. 9, each of the power semiconductors 200 includes a MOSFET and a built-in diode. In another example, each of the power semiconductors 200 may include a switching device such as an IGBT or a BJT instead of the MOSFET. Also, each of the power semiconductors 200 may not include the built-in diode or may include an external diode such as SiC-SBD instead of the built-in diode.

The control circuit 100 has a function and configuration similar to any of aspects described in FIGS. 1 to 8. The control circuit 100 controls each of the power semiconductors 200. Each of the power semiconductors 200 may be provided with the control circuit 100 described in FIGS. 1 to 8.

The semiconductor module 210 includes a module case which accommodates the power semiconductors 200. The module case may be made of resin or the like. The control circuit 100 may be arranged in the module case. The control circuit 100 may also be arranged outside the module case.

The isolation circuit 220 transmits a signal between the control circuit 100 and the microcontroller 230 while maintaining electrical isolation between them. The isolation circuit 220 may include a photocoupler, for example. In this way, even when the control circuit 100 and the microcontroller 230 operate at different power supply voltages, the isolation circuit 220 can transmit the signal between the control circuit 100 and the microcontroller 230.

The microcontroller 230 sends a signal to the control circuit 100 based on an instruction signal input externally. For example, the microcontroller 230 may generate the input signal V_{IN} based on the instruction signal and send it to the control circuit 100. Also, the microcontroller 230 may receive a signal from the control circuit 100. For example, the microcontroller 230 may receive a signal which represents a state of the control circuit 100, such as whether the control circuit 100 detects the overcurrent. The microcontroller 230 may send a notification of the signal to outside or may generate the input signal V_{IN} based on the signal.

While the present invention has been described above with the embodiments, the technical scope of the present invention is not limited to the above-described embodiments. It is apparent to persons skilled in the art that various changes or improvements can be made to the above-described embodiments. It is also apparent from description of the claims that the embodiments to which such changes or improvements are made may be included in the technical scope of the present invention.

What is claimed is:

1. A control circuit for a power semiconductor which operates depending on a control signal applied to a control terminal, comprising:
a detection value comparison unit which compares a current detection value depending on a main current flowing through the power semiconductor and a set current threshold;
a protection unit which, when a state in which the current detection value exceeds the current threshold has lasted longer than a set duration, suppresses the main current flowing through the power semiconductor; and
a protection control unit which controls at least any one of the current threshold, the duration, or an extraction rate of electric charges from the control terminal based on a control power supply voltage which determines an amplitude of the control signal.

2. The control circuit according to claim 1, wherein the protection control unit controls the current threshold.

3. The control circuit according to claim 2, wherein
the protection unit comprises:
a first protection device which, when the state in which the current detection value exceeds the current threshold has lasted longer than the set duration, suppresses the main current flowing through the power semiconductor; and
a second protection device which, when the state in which the current detection value exceeds the current threshold has lasted longer than the set duration and the control power supply voltage exceeds a set voltage threshold, further suppresses the main current flowing through the power semiconductor.

4. The control circuit according to claim 3, further comprising:
a set/reset latch which retains and outputs a current comparison result in the detection value comparison unit and sets an output as an initial value when the control signal indicates a logical value which indicates that the power semiconductor should be turned off, wherein
the protection control unit outputs a voltage comparison result between the control power supply voltage and the voltage threshold,
the first protection device operates depending on an output from the set/reset latch, and
the second protection device operates based on a logical AND of an output from the set/reset latch and the voltage comparison result.

5. The control circuit according to claim 4, further comprising:
an OR circuit which outputs a logical OR of an output from the set/reset latch and the control signal; and
a charge and discharge control unit which controls whether the control terminal of the power semiconductor is charged, depending on an output from the OR circuit.

6. The control circuit according to claim 1, wherein
the protection control unit controls the duration.

7. The control circuit according to claim 1, wherein
the protection control unit controls the extraction rate.

8. The control circuit according to claim 7, further comprising
an extraction transistor which controls whether the control terminal is connected to a reference potential, wherein
the protection control unit controls at least one of a channel area of the extraction transistor or a gate voltage applied to the extraction transistor.

9. The control circuit according to claim 7, further comprising:
a discharge resistor provided on a path for discharging the control terminal, wherein
the protection control unit controls a resistance value of the discharge resistor.

10. The control circuit according to claim 8, wherein
the protection control unit further controls the current threshold, and
the protection control unit changes the current threshold and then controls the extraction transistor of which the extraction rate has changed to assume an ON state.

11. A power supply circuit comprising:
the control circuit according to claim 1; and
the power semiconductor.

12. A power supply circuit comprising:
the control circuit according to claim 2; and
the power semiconductor.

13. A power supply circuit comprising:
the control circuit according to claim 3; and
the power semiconductor.

14. A power supply circuit comprising:
the control circuit according to claim 4; and
the power semiconductor.

15. A power supply circuit comprising:
the control circuit according to claim 5; and
the power semiconductor.

16. A power supply circuit comprising:
the control circuit according to claim 6; and
the power semiconductor.

17. A power supply circuit comprising:
the control circuit according to claim 7; and
the power semiconductor.

18. A power supply circuit comprising:
the control circuit according to claim 8; and
the power semiconductor.

19. A power supply circuit comprising:
the control circuit according to claim 9; and
the power semiconductor.

20. A power supply circuit comprising:
the control circuit according to claim 10; and
the power semiconductor.
